(19) United States
(12) Patent Application Publication
(10) Pub. No.: US 2022/0412780 A1
(43) Pub. Date: Dec. 29, 2022

(54) DEVICE COMPRISING AN ELECTRONICS HOUSING AND A FUNCTIONAL HOUSING

(71) Applicant: Hella GmbH & Co. KGaA, Lippstadt (DE)

(72) Inventors: Tobias Lass, Warstein (DE); Danny Reichel, Menden (Sauerland) (DE)

(21) Appl. No.: 17/823,319

(22) Filed: Aug. 30, 2022

Related U.S. Application Data
(63) Continuation of application No. PCT/EP2021/054381, filed on Feb. 23, 2021.

(30) Foreign Application Priority Data
Mar. 3, 2020 (DE) 10 2020 105 685.0

(51) Int. Cl. G01D 11/24; H05K 5/00; H02K 5/10; H02K 11/20

(52) U.S. Cl. CPC G01D 11/245; H05K 5/0065; H02K 5/10; H02K 11/20

(57) ABSTRACT

A device is provided with an electronics housing for accommodating electronics for a sensor or an actuator, and a functional housing separate from the electronics housing in a disassembled state of the device. The functional housing accommodates the sensor or the actuator. The two housings are connected to each other in an assembled state of the device. During the transfer of the device into its assembled state, the housings can be connected in a form-locked manner to each other only by a linear movement thereof relative to each other along an assembly axis. The two housings include latch mechanisms corresponding to each other for this purpose.

### CROSS REFERENCE

This application claims priority to PCT Application No. PCT/EP2021/054381, filed Feb. 23, 2021, which itself claims priority to German Patent Application No. 10 2020 105685.0, filed Mar. 3, 2020, the entireties of both of which are hereby incorporated by reference.

### FIELD OF THE INVENTION

The present invention relates to a device that includes an electronics housing a functional housing.

### BACKGROUND OF THE INVENTION

Such devices, comprising an electronics housing for accommodating electronics for a sensor or an actuator and a functional housing separate from the electronics housing in a disassembled state of the device for accommodating the sensor or the actuator, the two housings being designed in such a way that the two housings are connected to each other in an assembled state of the device, are already known from the prior art in numerous embodiment variants.

### BRIEF SUMMARY OF THE INVENTION

It is a task of the present invention to provide a device comprising an electronics housing and a functional housing, wherein the transfer to an assembled state of the device and the assembled state of the device are improved.

The device is characterized in that the two housings are designed in such a way that, when the device is transferred to its assembled state, they can be connected to each other in form-locked manner only by means of a linear movement of the two housings relative to each other along an assembly axis, the two housings having mutually corresponding latching means or latch mechanism for this purpose.

In particular, one significant advantage of the inventive device is that the transfer into an assembled state of the device and the assembled state of the device are improved. Due to the design of the inventive device, a transfer of the device into its assembled state is realized in a structurally particularly simple and robust manner. Furthermore, with the invention, high forces can be transmitted between the functional housing on one side and the electronics housing on the other side in the assembled state of the device without impairing the function of the device.

In principle, the device can be selected at will within wide suitable limits in terms of type, functioning, dimensions, material and type.

One advantageous refinement of the inventive device element specifies that the functional housing is designed as a completely closed housing. In this way, the sensor or actuator located inside the functional housing is optimally protected against environmental influences that are detrimental to its functioning.

One alternative advantageous refinement of the inventive device specifies that the two housings are designed in such a way that the sensor or actuator arranged in the functional housing, in the assembled state of the device with an actuating element, engages with the electronics arranged in the electronics housing in such a way that an electrical or electronic signal can be generated in the electronics by means of the actuating element. As a result, sensors and actuators can also be used with the inventive device, in which engagement of an actuating means of the sensor or the actuator with the electronics arranged in an interior of the electronics housing is required.

One further advantageous refinement of the inventive device specifies that the functional housing is of circular-cylindrical design and the electronics housing has a correspondingly designed circular-ring-shaped receiving projection for partially receiving the functional housing in an interior of the electronics housing. In this way, the connection between a circular cylindrical functional housing and the electronics housing is made possible in a particularly advantageous and structurally simple manner.

Another advantageous refinement of the inventive device specifies that, in the assembled state of the device, a circumferential seal is arranged between the functional housing and the electronics housing in such a way that the two housings are tightly connected to each other in the assembled state of the device. This allows a tight connection between the electronics housing and the functional housing of the inventive device to be realized in a particularly simple manner.

One advantageous refinement of the aforementioned embodiment of the inventive device specifies that the seal is arranged in a region of the latching means of the two housings, wherein the seal is arranged between the latching means latched to each other on one side and the free environment on the other side in the assembled state of the device. In this way, the tightness of the device in its assembled state is reliably ensured, irrespective of a mode of operation of the mutually corresponding latching means.

One further advantageous refinement of the inventive device specifies that the mutually corresponding latching means of the two housings are formed as at least one latching lug and as at least one latching receptacle, preferably that the latching lugs are distributed uniformly around a circumference of one of the surfaces of the two housings facing each other in the assembled state of the device on the housing corresponding to the latching lugs and the latching receptacle is arranged circumferentially on the other one of the surfaces facing each other on the housing corresponding to the latching receptacle. This allows the latching means of the electronics housing and the functional housing to be realized in a structurally particularly simple and robust manner. This applies in particular to the preferred embodiment of this refinement.

One advantageous refinement of the aforementioned embodiment of the inventive device specifies that the latching lug features an insertion bevel and an end stop on a side of the latching lug facing the housing featuring the latching receptacle when the device is transferred into its assembled state and/or is formed with an oversize relative to the latching receptacle on a side facing away from the housing having the latching receptacle when the device is transferred into its assembled state. Firstly, in this way, transfer of the device into its assembled state is facilitated by means of the insertion bevel and it is secured in the assembled state by means of the end stop. Secondly, in the assembled state of the device, the electronics housing and the functional housing are properly connected to each other by means of the latching lug, which is oversized in relation to the latching receptacle, even under difficult ambient conditions, for example in the event of vibrations or the like, and thus ensure the functioning of the device.

One further advantageous refinement of the inventive device specifies that at least one centering element, preferably a plurality of centering elements distributed uniformly over the circumference of one of the surfaces of the two housings facing each other in the assembled state of the device, is/are arranged on the electronics housing and/or on the functional housing for centering the two housings relative to each other in the assembled state of the device. This ensures the correct alignment of the two housings of the device in the assembled state of the device transverse to the assembly axis for proper functioning of the device.

Another advantageous refinement of the inventive device specifies that coding means corresponding to each other are arranged on the electronics housing and on the functional housing for transferring the device into its assembled state in the correct position, preferably that the coding means are at the same time designed as anti-rotation means to counter undesired rotation of the two housings relative to each other around the assembly axis in the assembled state of the device. In this way, a correct rotational position of the device relative to the assembly axis in the device's assembled state is ensured in a structurally simple and robust manner for proper operation of the device. This applies in particular to the preferred embodiment of this refinement.

One especially advantageous refinement of the last-mentioned embodiment of the inventive device specifies that the coding means are at least partially designed at the same time as centering means. This increases the functionality of the coding means so that, for example, the number of components required is reduced and/or the design of the electronics housing and/or the functional housing is simplified. Accordingly, the manufacture of the inventive device is also simplified, which leads to a reduction in manufacturing costs.

### BRIEF DESCRIPTION OF THE DRAWINGS

Reference is now made more particularly to the drawings, which illustrate the best presently known mode of carrying out the invention and wherein similar reference characters indicate the same parts throughout the views.

FIG. 1 illustrates a sample embodiment of the inventive device in a partial perspective view, in the disassembled state of the device.

FIG. 2 illustrates the sample embodiment of FIG. 1, in the assembled state of the device.

FIG. 3 illustrates the sample embodiment in a partial sectional view in the area of the latching means, in the assembled state of the device.

FIG. 4 illustrates the sample embodiment in a partial top view, in the assembled state of the device.

FIG. 5 illustrates the functional housing of the sample embodiment in a perspective single view.

### DETAILED DESCRIPTION OF THE DRAWINGS

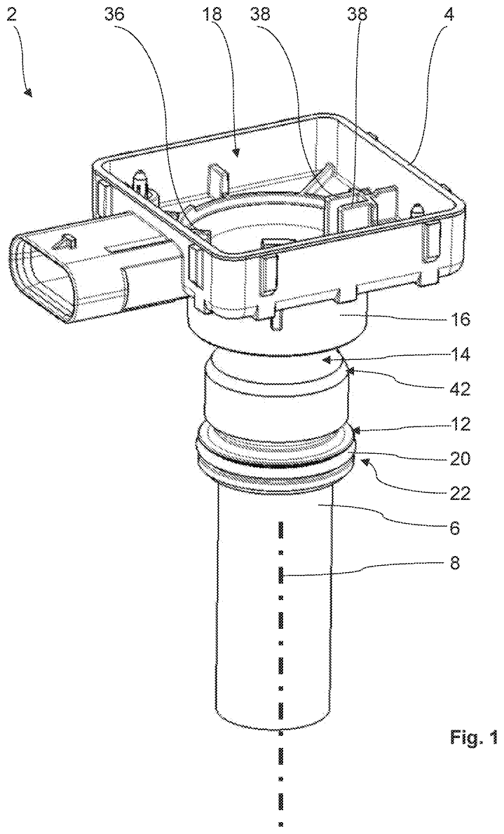

FIGS. 1 through 5 show a sample embodiment of the inventive device as an example.

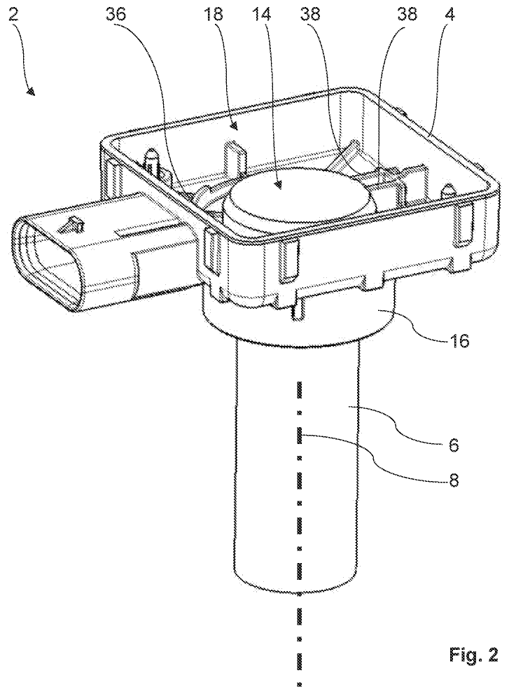

The device 2 is designed for use in a motor vehicle and comprises an electronics housing 4 for accommodating electronics, which are not shown, for an actuator, which is not shown, and a functional housing 6, which is separate from the electronics housing 4 in a disassembled state of the device 2 shown in FIG. 1, for accommodating the actuator, the two housings 4, 6 being designed in such a way that the two housings 4, 6 are connected to each other in an assembled state of the device 2 shown in FIGS. 2 to 4. In the present sample embodiment, the actuator is designed as a linear actuator for a valve that is also not shown. The electronics housing 4 and the functional housing 6 are each formed as a plastic injection molded part.

The two housings 4, 6 are designed in such a way that, when the device 2 is transferred into its assembled state, they can be connected to each other in a form-locked manner by means of a linear movement of the two housings 4, 6 relative to one another along an assembly axis 8, the two housings 4, 6 having latching means 10, 12 corresponding to each other for this purpose. The latching means 10, 12 are each formed as an integral part of the corresponding housing 4, 6.

In the present sample embodiment, the two housings 4, 6 are designed in such a way that the actuator arranged in the functional housing 6 is in engagement with the electronics arranged in the electronics housing 4 by means of an actuating element, which is not shown, in the assembled state of the device 2 in such a way that an electrical or electronic signal can be generated in the electronics by means of the actuating element. For this purpose, the functional housing 6 features at least one opening, not shown, for the actuating element in a cover 14 of the functional housing 6. For the purpose of actuating the valve, which is not shown, by means of the actuator, the functional housing 6 also has a further opening, which is not shown, in a bottom opposite the cover 14. In principle, however, it is also conceivable that the functional housing in other embodiments of the inventive device is designed as a completely closed housing.

As can be seen from a synopsis of FIGS. 1 to 5, the functional housing 6 is of circular-cylindrical design and the electronics housing 4 has a correspondingly designed circular-ring-shaped receiving projection 16 for partially receiving the functional housing 6 in an interior 18 of the electronics housing 4. The electronics housing 4 is only partially shown in FIGS. 1, 2 and 4, so that in FIGS. 1, 2 and 4 the view of the interior 18 of the electronics housing 4, in which the electronics (not shown) are arranged, is unobstructed.

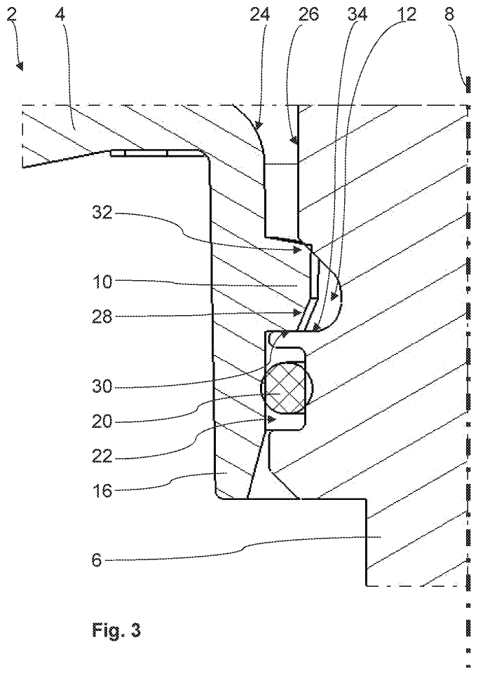

In the assembled state of the device 2 shown in FIGS. 2 to 4, a circumferential seal 20 is arranged between the functional housing 6 and the electronics housing 4 in such a way that the two housings 4, 6 are tightly connected to each other in the assembled state of the device 2. In the present sample embodiment, the seal 20 is formed as a sealing ring 20 arranged in a sealing groove 22 of the functional housing 6. As further shown in FIGS. 2, 3 and 5, the seal 20 is arranged in a region of the latching means 10, 12 of the two housings 4, 6, the seal 20 being arranged between the latching means 10, 12 latched together on one side and the free environment on the other side in the assembled state of the device 2. In this context, see in particular FIG. 3.

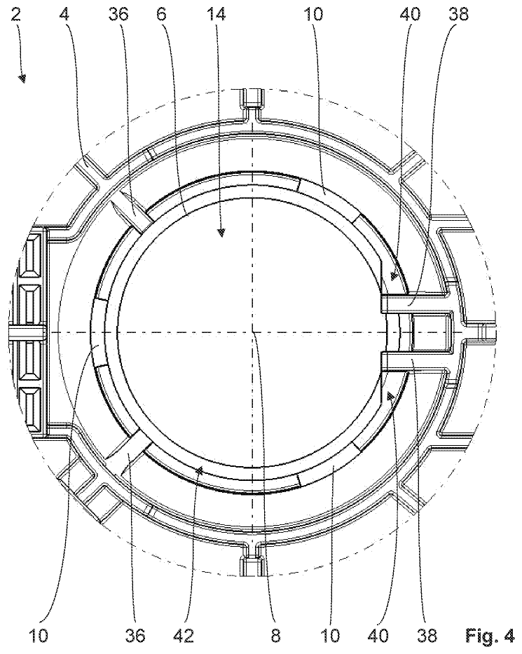

In the present sample embodiment, the latching means 10, 12 of the two housings 4, 6, which are designed to correspond to each other, are designed as a total of three latching lugs 10 and as a latching receptacle 12, the latching lugs 10 being distributed uniformly around a circumference of one of the surfaces 24 of the two housings 4, 6 facing each other in the assembled state of the device 2 on the housing 4 corresponding to the latching lugs 10, and the latching receptacle 12 is arranged circumferentially on the other one of the surfaces 26 facing each other on the housing 6 corresponding to the latching receptacle 12. In this context, see in particular FIGS. 3 and 4.

The latching lugs 10 each feature an insertion bevel 28 and an end stop 30 on a side of the respective latching lug 10 facing the housing 6 featuring the latching receptacle 12 when the device 2 is transferred into its assembled state, and are formed with an oversize relative to the latching receptacle 12 on a side 32 facing away from the housing 6 featuring the latching receptacle 12 when the device 2 is transferred into its assembled state. See in particular FIG. 3, in which a latching lug 10 and the latching receptacle 12 are shown by way of example. However, the same applies to the other latching lugs 10. As can be seen from FIG. 3, the end stop 30 of the latching lug 10 of the electronics housing 4 interacts with a shoulder 34 of the functional housing 6 in such a way that, when the device 2 is transferred to its assembled state, the functional housing 6 can only be pushed into the receiving projection 16 of the electronics housing 4 along the assembly axis 8 up to the predetermined point. The formation of the latching lugs 10 with oversize on the side 32 of the latching lugs 10 interacts with the latching receptacle 12 in the assembled state of the device 2 in such a way that the latching lugs 10 each engage in the latching receptacle 12 under pretension. One material of the electronics housing 4 is correspondingly elastic.

Furthermore, two centering elements 36 are arranged on the electronics housing 4 for centering the two housings 4, 6 with respect to each other in the assembled state of the device 2. In addition, two coding means 38 are arranged on the electronics housing 4. On the one hand, the two coding means 38 also act as centering elements for centering the two housings 4, 6 with respect to each other in the assembled state of the device 2. Accordingly, the electronics housing 4 thus features a total of four centering elements 36, 38 for centering the two housings 4, 6 relative to each other in the assembled state of the device 2, the centering elements 36 and the coding means 38 being arranged on the electronics housing 4 as a pair distributed uniformly over the circumference of the surface 24 of the surfaces facing each other 24, 26 of the two housings 4, 6.

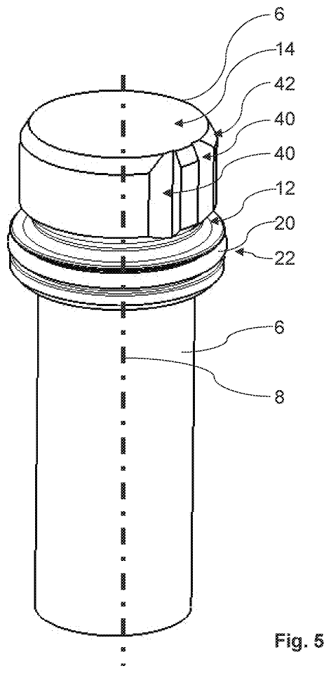

On the other hand, the coding means 38 interact with coding means 40, which are arranged on the functional housing 6 and are designed to correspond to the coding means 38, for transferring the device 2 into its assembled state in the correct position, the coding means 38, 40 being designed at the same time as anti-rotation means 38, 40 to counter undesired rotation of the two housings 4, 6 relative to each other around the assembly axis 8 in the assembled state of the device 2. In this context, see in particular FIGS. 4 and 5. In contrast to the centering elements 36 of the electronics housing 4, which merely rest against the functional housing 6, the coding means 38 of the electronics housing 4 engage in a form-locked manner with the coding means of the functional housing 6. This embodiment can be realized more cost-effectively than if the centering elements of the sample embodiment were replaced, for example, by coding means analogous to the sample embodiment.

The centering means 36 and the coding means 38, 40 are each formed as an integral part of the corresponding housing 4, 6.

The functioning of the inventive device according to the present sample embodiment is explained in more detail in the following on the basis of FIGS. 1 through 5.

Initially, the device 2 is in its disassembled state. See FIGS. 1 and 5. For the purpose of transferring the device 2 into its assembled state shown in FIGS. 2 to 4, the following procedure is now followed:

The functional housing 6 is connected to the electronics housing 4 manually, semi-automatically or fully automatically. For this purpose, the functional housing 6 with the seal 20 arranged thereon is first inserted into the receiving projection 16 of the electronics housing 4 along the assembly axis 8, namely from bottom to top in the image plane of FIG. 1. This insertion of the functional housing 6 into the receiving projection 16 of the electronics housing 4 is facilitated by an insertion bevel 42 formed on the cover 14 of the functional housing 6.

In the process, the latching lugs 10 of the electronics housing 4 engage with the latching receptacle 12 of the functional housing 6. This is facilitated by the insertion bevel 28 formed on each of the latching lugs 10. As soon as each of the latching lugs 10 rests with its end stop 30 against the shoulder 34 formed on the functional housing 6, the functional housing 6 cannot be inserted further into the electronics housing 4. At the same time, the latching lugs 10 jam with the latching receptacle 12 by means of the oversize formed on the side 32 of the latching lugs 10 in each case, so that the latching lugs 10 of the electronics housing 4 engage in the latching receptacle 12 of the functional housing 6 in each case under pretension. In the process, the latching lugs 10 deform elastically due to the oversize.

During the aforementioned transfer of the device 2 into its assembled state, the functional housing 6 is supported on the centering elements 36 and the coding means 38, which are also formed as centering elements, in order to align the functional housing 6 transversely to the assembly axis 8 relative to the electronics housing 4. Furthermore, the coding means 38 of the electronics housing 4 cooperate with the corresponding coding means 40 in such a way that the functional housing 6 can only be inserted into the electronics housing 4 in a rotational position relative to the assembly axis 8. In this context, see in particular FIGS. 4 and 5. In the assembled state of the device 2, the coding means 38, 40 simultaneously act as anti-rotation means to prevent unwanted rotation of the functional housing 6 about the assembly axis 8 relative to the electronics housing 4. In this context, see likewise FIGS. 4 and 5.

As can be clearly seen from FIG. 3, the seal 20, which is formed as a circumferential sealing ring, is arranged in the sealing groove 22 formed on the functional housing 6 in such a way that the seal 20 is compressed by the surface 24 of the electronics housing 4 of the facing surfaces 24, 26 facing each other of the two housings 4, 6 in such a way that the seal 20 bears to form a seal between the electronics housing 4 on one side and the functional housing 6 on the other side.

Thus, in the device 2 according to the present sample embodiment, the transfer of the device 2 into its assembled state and the assembled state of the device 2 are improved. Due to the inventive design of the device 2, a transfer of the device 2 into its assembled state is realized in a structurally particularly simple and robust manner. Furthermore, in the assembled state of the device 2, high forces can be transmitted between the functional housing 6 on one side and the electronics housing 4 on the other side without impairing the functioning of the device 2. The seal 20 arranged between the electronics housing 4 and the functional housing 6 also provides a secure seal of the device 2 against the free environment, so that the interior of the device 2, i.e. the interior 18 of the electronics housing 4, namely the electronics, and the interior of the functional housing 6, namely the actuator, are effectively protected against environmental influences detrimental to the functioning of the device 2.

The invention is not limited to the present sample embodiment. The inventive device can also be advantageously deployed with other application scenario for example. For example, a sensor can be arranged in the functional housing as an alternative or in addition to the actuator. Furthermore, the functional housing can be designed as a completely closed housing. The specific embodiments of the sample embodiment explained above are purely exemplary and not limiting. Accordingly, the inventive device can be used for a wide range of applications, even outside the field of automotive engineering. For example, it is possible that the at least one latching lug is arranged on the functional housing and the at least one latching receptacle is arranged on the electronics housing. The at least one centering element may also be arranged on the functional housing as an alternative to the present sample embodiment. However, an arrangement of a plurality of centering elements on both the electronics housing and the functional housing is also conceivable.

### LIST OF REFERENCE NUMBERS

2 Device
4 Electronics housing
6 Functional housing
8 Assembly axis
10 Latching means, designed as a latching lug
12 Latching means, designed as a latching receptacle
14 Cover of the functional housing 6
16 Receiving projection
18 Interior of the electronics housing 4
20 Seal, designed as a sealing ring
22 Sealing groove
24 Area of the surfaces of the housings 4, 6 facing the device 2 in the assembled state
26 Area of the surfaces of the housings 4, 6 facing the device 2 in the assembled state
28 Insertion bevel of the latching lug 10
30 End stop of the latching lug 10
32 Side of latching lug 10
34 Shoulder of the functional housing 6
36 Centering element
38 Coding means, simultaneously designed as centering element
40 Coding means
42 Insertion bevel of the functional housing 6

We claim:

1. A device comprising:
an electronics housing accommodating electronics for a sensor or an actuator; and
a functional housing separate from the electronics housing in a disassembled state of the device, the functional housing accommodating the sensor or the actuator,
wherein the electronics housing and the functional housing are connected to each other in an assembled state of the device,
wherein when the device is transferred to its assembled state, the electronics housing and the functional housing are connectable to each other in a form-locked manner by a linear movement of the electronics housing and the functional housing relative to each other along an assembly axis,
wherein the electronics housing and the functional housing each having a latch mechanism corresponding to each other for connecting the electronics housing with the functional housing.

2. The device of claim 1, wherein the functional housing is a completely closed housing.

3. The device of claim 1, further including an actuating element, and
wherein in the assembled state of the device, the sensor or actuator engages with the electronics arranged in the electronics housing such that an electrical or electronic signal is generated in the electronics by the actuating element.

4. The device in accordance with claim 1, wherein the functional housing circular-cylindrical and the electronics housing includes a correspondingly circular-ring-shaped receiving projection for partially receiving the functional housing in an interior of the electronics housing.

5. The device in accordance with claim 1, wherein in the assembled state of the device, a circumferential seal is arranged between the functional housing and the electronics housing such that the functional housing and the electronic housing are connected to each other in a sealed manner.

6. The device in accordance with claim 5, wherein the seal is arranged in a region of the latch mechanism of the electronic housing and the functional housing, the seal being arranged, in the assembled state of the device, between the latch mechanisms latched to each other on the one side and the free environment on the other side.

7. The device in accordance with claim 1, wherein the corresponding latch mechanisms of the electronic housing and the functional housing are respectively at least one latching lug and as at least one latching receptacle.

8. The device in accordance with claim 7, wherein the at least one latching lug has an insertion bevel and an end stop on a side of the at least one latching lug facing the housing having the latching receptacle when the device is transferred into its assembled state, and/or is formed with an oversize relative to the latching receptacle on a side facing away from the housing featuring the latching receptacle when the device is transferred into its assembled state.

9. The device in accordance with claim 1, wherein at least one centering element is arranged on the electronics housing and/or on the functional housing for centering the electronic housing and the functional housing with respect to each other in the assembled state of the device.

10. The device in accordance with claim 9, wherein coding means corresponding to each other are arranged on the electronics housing and on the functional housing for transferring the device in the correct position into its assembled state.

11. The device in accordance with claim 10, wherein the coding means are anti-rotation means to counter undesired rotation of the two housings relative to each other around the assembly axis in the assembled state of the device.

12. The device in accordance with claim 9, wherein the coding means are at least partially designed at the same time as centering element.
